(19) United States
(12) Patent Application Publication
(10) Pub. No.: US 2007/0193724 A1
(43) Pub. Date: Aug. 23, 2007

(54) Heat dissipating device

(76) Inventor: Sheng-Huang Lin, Taipei (TW)

Correspondence Address: G. LINK CO. LTD., 3550 BELL ROAD, MINOOKA, IL, 60447, US

(21) Appl. No.: 11/356,055

(22) Filed: Feb. 17, 2006

(51) Int. Cl. H05K 7/20

(52) U.S. Cl. 165/121; 361/697; 165/80.3; 165/104.33

(57) ABSTRACT

A heat dissipating device includes a radiator and a fan. The fan has a fan blade part and a fan frame and the radiator has a plurality of cooling fins. Further, the radiator has an opening passing through the cooling fins from a lateral side of the radiator. The fan is inserted into the opening and fixedly joined to the opening.

### BACKGROUND OF THE INVENTION

1. Field of the Invention

The present invention is related to a heat dissipating device particularly to a heat dissipating device, which provides a radiator and a fan and an opening passing through all the cooling fins thereof for the fan being inserted into and joined to the opening.

2. Brief Description of the Related Art

Taiwanese Patent Publication No. 532738 discloses a cylindrical recess is provided at the center of the top of the cooling fins for receiving an internal fan. However, the internal fan has to be mounted to an external fan in series before being disposed in the radiator. As a result, the fabricating cost is high due to a lot of parts being required.

Taiwanese Patent Publication No. 577585 discloses a first and a second radiators and each of the radiators provides two fans at the top thereof. However, when a fan are mounted between the first and second radiators, it is inconvenient for the fan being set up in place due to being impeded by the second radiator on top of the fan.

Taiwanese Patent Publication No. M243002 discloses cooling fins of the radiator provides a groove for receiving a fan at the upper front half section and the upper rear half section respectively. However, the fan is fixedly attached to the cooling fins by a clamping device at a side of the fan and it is incapable of subduing vibration occurring during the fan being in operation by means of the clamping device only. As a result, the fan is unable to run steadily and it may be even worse to create noise due to high vibration frequency. The fan running under the unsteady state in a long period of time is easy to become damaged.

Taiwanese Patent Publication No. M250226 discloses a fan device between a first heat dissipating member and a second heat dissipating member. However, it is required to employ air shield in order to allow the fan being fixed between the first heat dissipating member and the second heat dissipating member. Hence, it is high cost and inconvenient for setting up the fan.

### SUMMARY OF THE INVENTION

In order to solve the preceding problems, an object of the present invention is to provide a heat dissipating device in which a radiator provides an opening passing through the cooling fins thereof for the fan being inserted into and joined to the opening.

Another object of the present invention is to provide a heat dissipating device with which the fan is capable of being joined to the radiator without clamping tool.

A further object of the present invention is to provide a heat dissipating device with low material cost.

A further object of the present invention is to provide a heat dissipating device, which is suitable for mounting either an axial flow fan or a centrifugal fan without changing design of the radiator.

A heat dissipating device according to the present invention includes a radiator and a fan. The fan has a fan blade part and a fan frame and the radiator has a plurality of cooling fins. Further, the radiator has an opening passing through the cooling fins from a lateral side of the radiator. The fan is inserted into the opening and fixedly joined to the opening.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of the first embodiment of a heat dissipating device according to the present invention;

FIG. 2 is an assembled perspective view of the first embodiment of a heat dissipating device according to the present invention;

FIG. 3 is a sectional view of the first embodiment of a heat dissipating device according to the present invention;

FIG. 4 is an exploded perspective view of the second embodiment of a heat dissipating device according to the present invention;

FIG. 5 is an assembled perspective view of the second embodiment of a heat dissipating device according to the present invention;

FIG. 6 is a sectional view of the second embodiment of a heat dissipating device according to the present invention;

FIG. 7 is an exploded perspective view of the third embodiment of a heat dissipating device according to the present invention;

FIG. 8 is an assembled perspective view of the third embodiment of a heat dissipating device according to the present invention;

FIG. 9 is a sectional view of the third embodiment of a heat dissipating device according to the present invention;

FIG. 10 is an exploded perspective view of the fourth embodiment of a heat dissipating device according to the present invention;

FIG. 11 is an assembled perspective view of the fourth embodiment of a heat dissipating device according to the present invention;

FIG. 12 is a sectional view of the third embodiment of a heat dissipating device according to the present invention;

FIG. 13 is an exploded perspective view of the fifth embodiment of a heat dissipating device according to the present invention;

FIG. 14 is an assembled perspective view of the fourth embodiment of a heat dissipating device according to the present invention;

FIG. 15 is a sectional view of the fifth embodiment of a heat dissipating device according to the present invention;

FIG. 16 is an exploded perspective view of the sixth embodiment of a heat dissipating device according to the present invention;

FIG. 17 is an assembled perspective view of the sixth embodiment of a heat dissipating device according to the present invention;

FIG. 18 is a sectional view of the sixth embodiment of a heat dissipating device according to the present invention;

FIG. 19 is an exploded perspective view of the seventh embodiment of a heat dissipating device according to the present invention;

FIG. 20 is an assembled perspective view of the seventh embodiment of a heat dissipating device according to the present invention;

FIG. 21 is a sectional view of the seventh embodiment of a heat dissipating device according to the present invention;

FIG. 22 is an exploded perspective view of the eighth embodiment of a heat dissipating device according to the present invention;

FIG. 23 is an assembled perspective view of the seventh embodiment of a heat dissipating device according to the present invention; and

FIG. 24 is a sectional view of the eighth embodiment of a heat dissipating device according to the present invention;

### DETAILED DESCRIPTION OF THE INVENTION

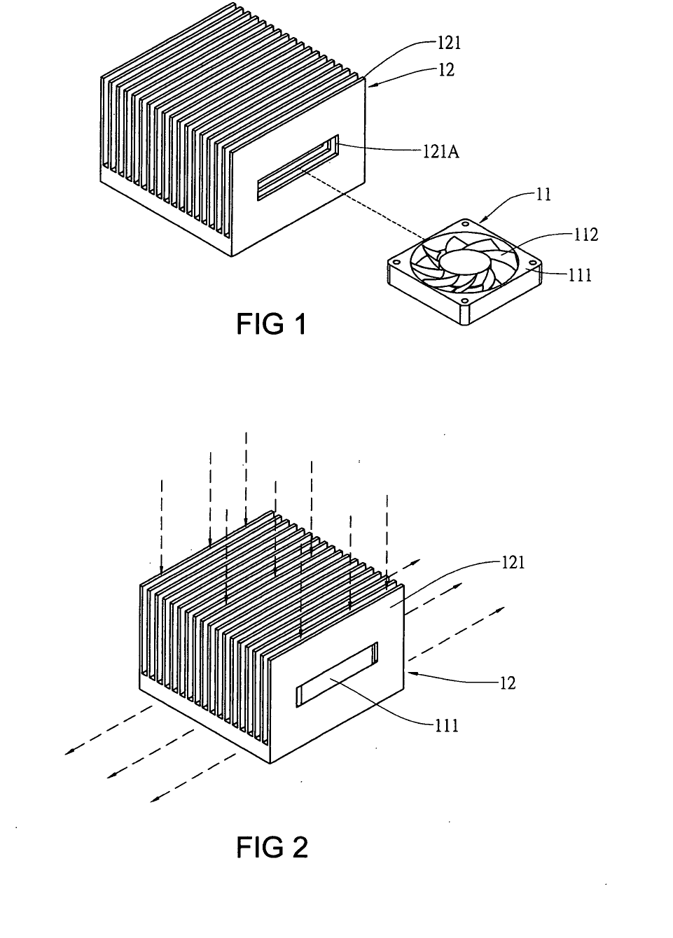

Referring to FIGS. 1 to 3, the first embodiment of a heat dissipating device according to the present invention includes a fan 11 and a radiator 12. The radiator 12 has a plurality of cooling fins 121 and the fan 11 has a fan blade part 111 and a fan frame 112. The radiator 12 has an opening 121A passing through facing sides of the cooling fins 121 and the opening 121A is capable of receiving the fan 11.

Referring to FIG. 2 again, the opening 121A provides a dimension equal to size of the fan frame 112 such that the fan 11 is able to be inserted into the opening 112A. The arrangement has the following advantages:

1. Vibration resulting from the fan 11 is capable of being subdued by the radiator 12.

2. When the fan 11 is mounted to the radiator, the mounting job is only simply inserting the fan 11 into the opening directly such that any hand tools or special techniques are not necessary once the fan 12 is detached from the radiator 12.

3. No air shield or locking tool is necessary while the fan 11 is mounted to the radiator so that it is better for use if it compares to the conventional heat dissipating device.

4. The fabricating cost and the material cost are low because joining the fan 11 to the radiator 12 needs simple and less parts.

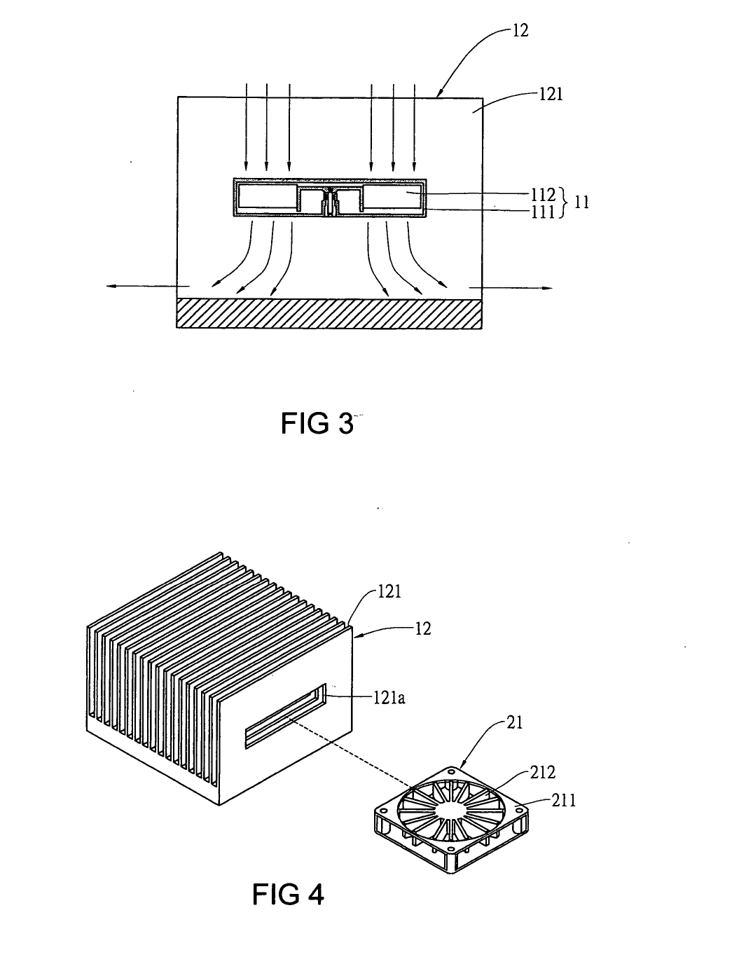

Referring to FIG. 3 again, the fan 11 is horizontal axial flow fan so that the air induced by the fan enters the radiator 12 from top thereof and moves outward via the bottom of the fan 11. When the fan blade part 111 rotates, the air around the top of the radiator 12 is induced via spaces between the cooling fins 121 instead of being interfered by the cooling fins and occurring turbulent flow as the conventional device does.

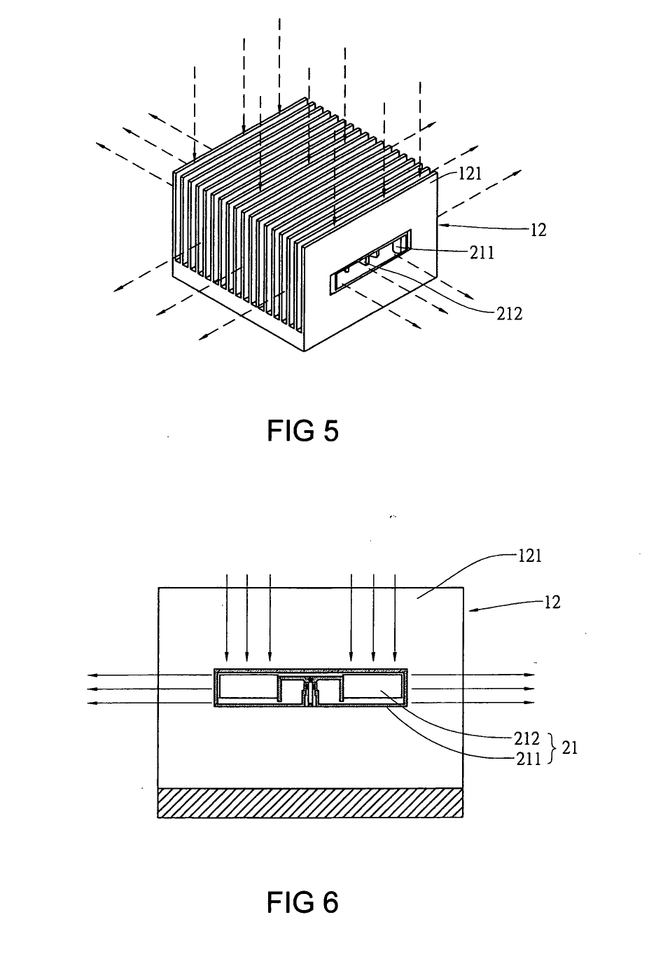

Referring to FIGS. 4 to 6, the second embodiment of a heat dissipating device according to the present invention is illustrated. A centrifugal fan 21 is employed to be inserted into the opening 121A in the present embodiment.

Referring to FIG. 6 again, the centrifugal fan 21 is a horizontal centrifugal fan so that the air is induced into the radiator 12 from the top thereof and moves outward via all the lateral sides thereof. When the fan blade part 211 rotates, the air around the top of the radiator 12 enters via spaces between the cooling fins 121 instead of being interfered by the cooling fins and occurring turbulent flow as the conventional device does.

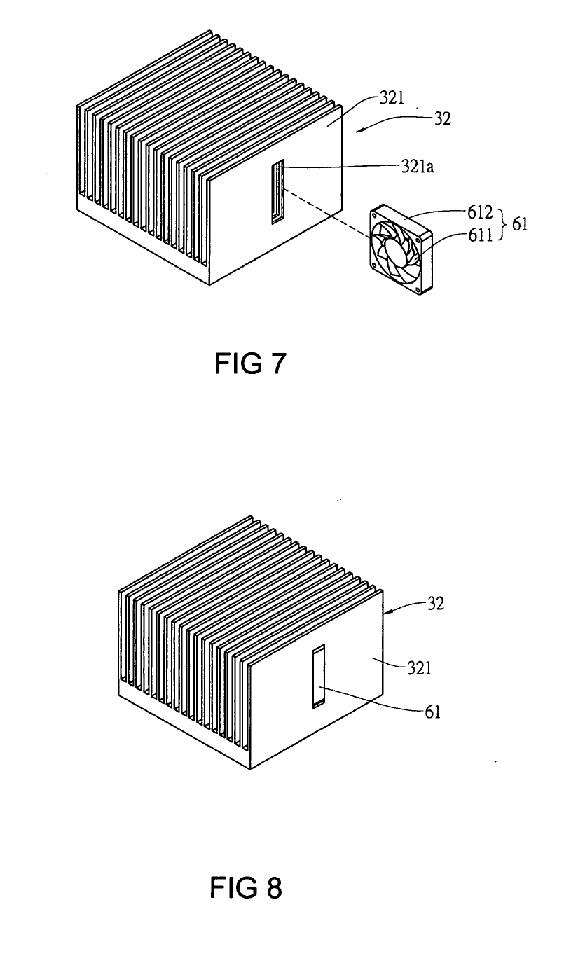

Referring to FIGS. 7 and 8, the third embodiment of a heat dissipating device according to the present invention is illustrated. The third embodiment is characterized in that a radiator 32 has a plurality of cooling fins 321 and provides an opening 321a passing through the cooling fins 321. The opening 321a is employed to be available for receiving a fan 61.

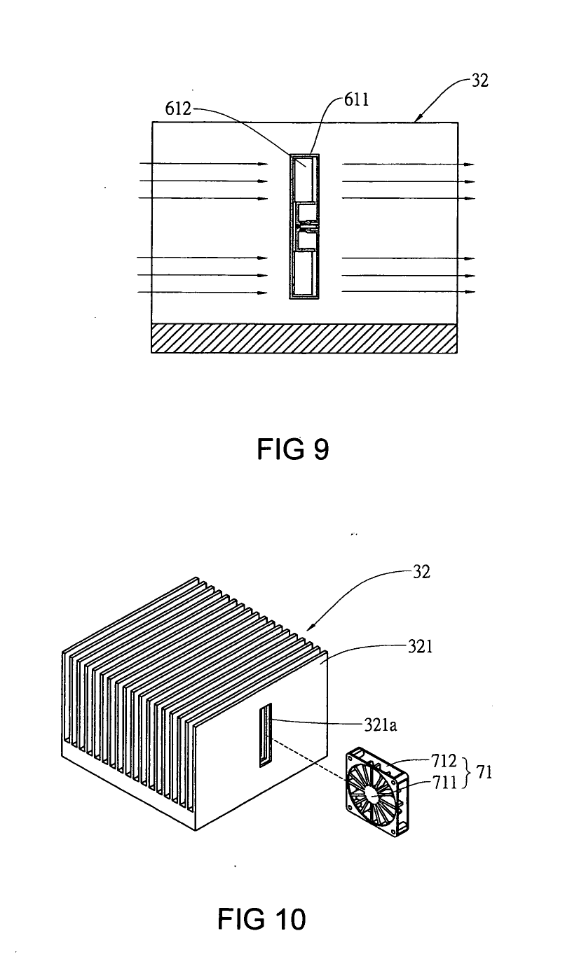

Referring to FIG. 9, the fan 61 is a vertical axial flow fan such that the air is induced into the radiator 32 from a lateral side thereof and moves outward via another lateral side thereof. When the fan blade part 611 rotates, the air enters the radiator 32 via spaces between the cooling fins 321 being interfered by the cooling fins and occurring turbulent flow as the conventional device does.

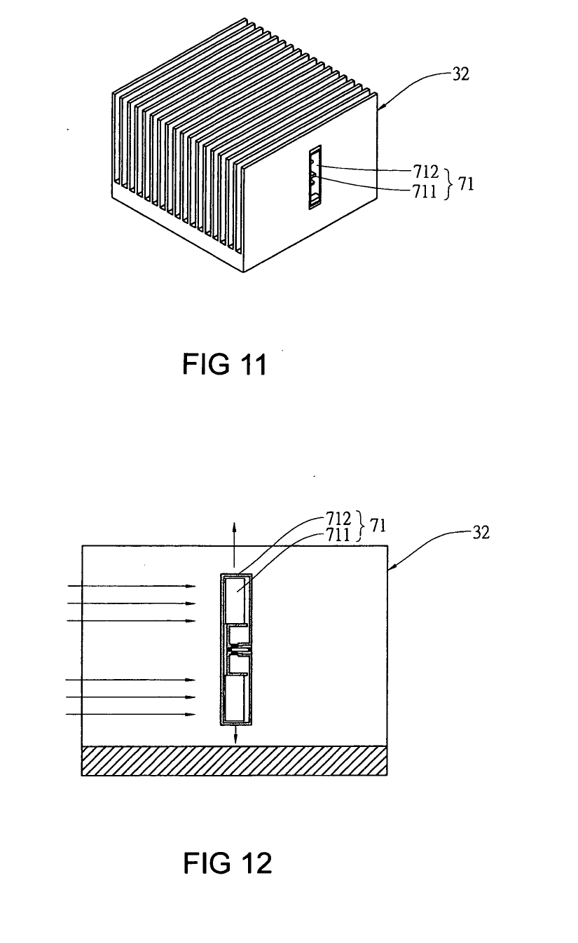

Referring to FIGS. 10 and 11, the fourth embodiment of a heat dissipating device according to the present invention is illustrated. The fourth embodiment is characterized in that a radiator 32 has a plurality of cooling fins 321 and provides an opening 321a passing through the cooling fins 321. The opening 321a is employed to be available for receiving a fan 71.

Referring to FIG. 12, the fan 71 is a vertical centrifugal fan such that the air is induced into the radiator 32 by the fan 71 from the top thereof and moves outward via all the lateral sides thereof. When the fan blade part 711 rotates, the air enters the radiator 32 via spaces between the cooling fins 321 being interfered by the cooling fins and occurring turbulent flow as the conventional device does.

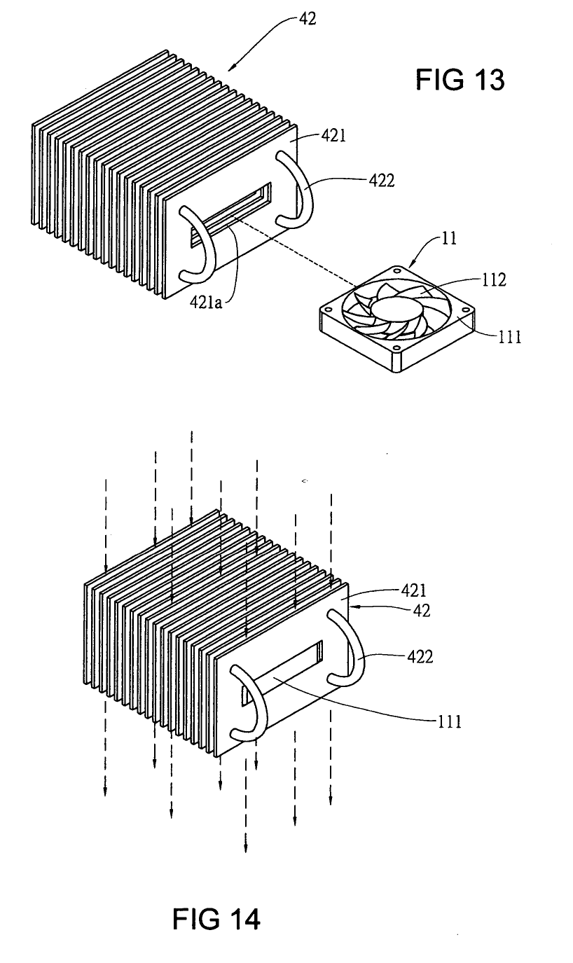

Referring to FIGS. 13 and 14, the fifth embodiment of a heat dissipating device according to the present invention is illustrated. The fifth embodiment is characterized in that a radiator 42 has a plurality of cooling fins 421 and guide heat pipes 422, wherein, the heat pipes 422 pass through the cooling fins 421 and an opening 421a is provided to pass through the cooling fins 421. The opening 421a is employed to be available for receiving a fan 11.

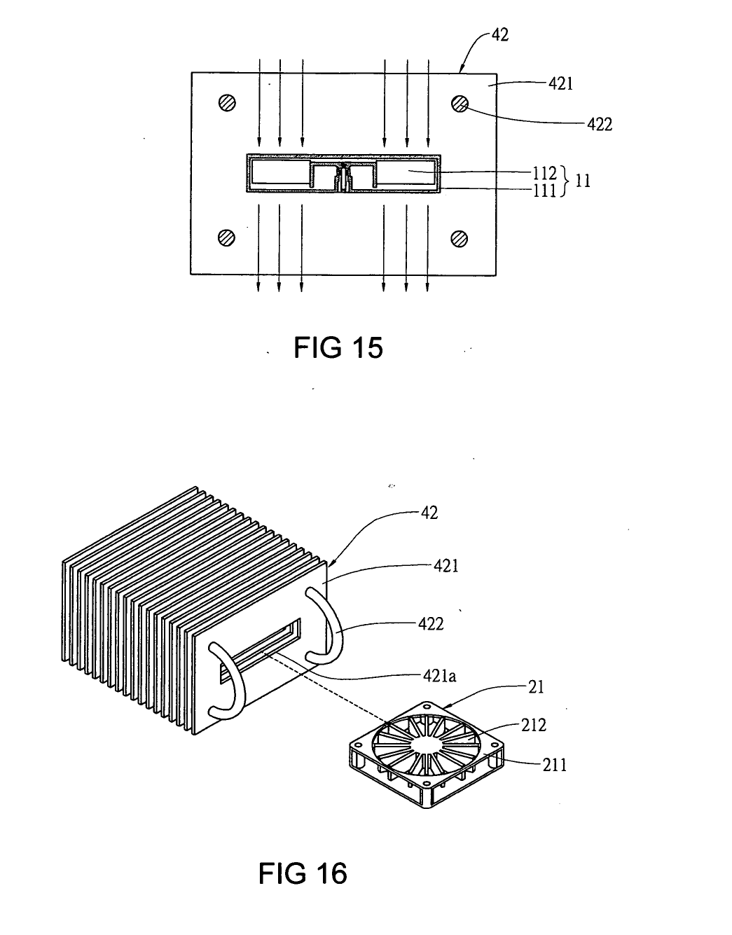

Referring to FIG. 15, the fan 11 is horizontal axial flow fan so that the air induced by the fan enters the radiator 42 from top thereof and moves outward via the bottom of the fan 11. When the fan blade part 111 rotates, the air around the top of the radiator 42 is induced via spaces between the cooling fins 421 instead of being interfered by the cooling fins 421 and occurring turbulent flow as the conventional device does.

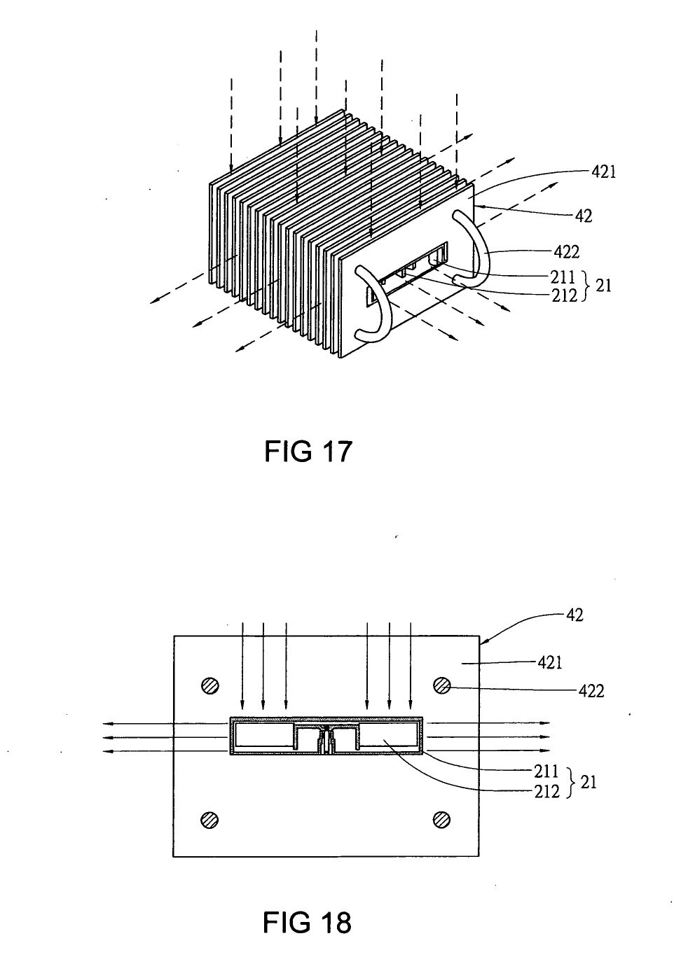

Referring to FIGS. 16 and 17, the sixth embodiment of a heat dissipating device according to the present invention is illustrated. The sixth embodiment is characterized in that a radiator 42 has a plurality of cooling fins 421 and guide heat pipes 422, wherein, the heat pipes 422 pass through the cooling fins 421 and an opening 421a is provided to pass through the cooling fins 421. The opening 421a is employed to be available for receiving a fan 21.

Referring to FIG. 18, the centrifugal fan 21 is a horizontal centrifugal fan so that the air is induced into the radiator 42 from the top thereof and moves outward via all the lateral sides thereof. When the fan blade part 211 rotates, the air around the top of the radiator 42 enters the radiator 42 via spaces between the cooling fins 421 instead of being interfered by the cooling fins and occurring turbulent flow as the conventional device does.

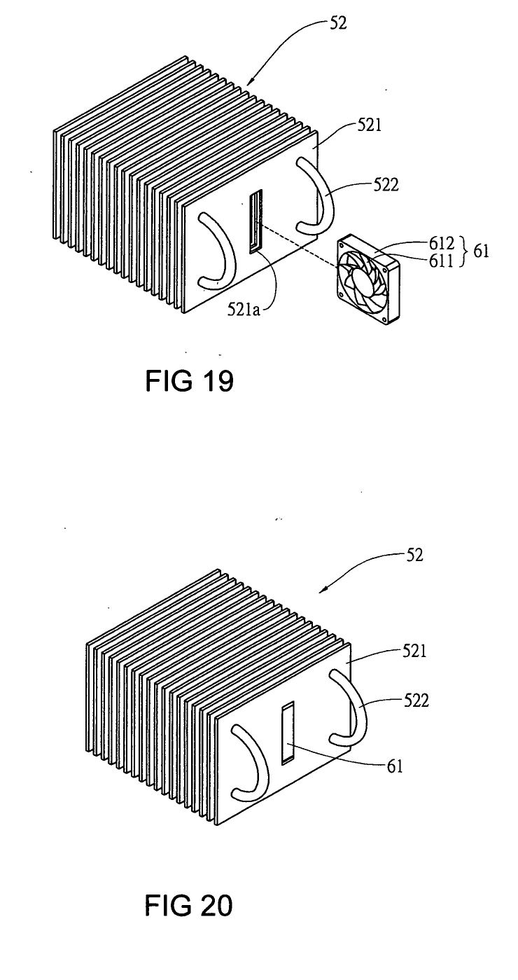

Referring to FIGS. 19 and 20, the seventh embodiment of a heat dissipating device according to the present invention is illustrated. The seventh embodiment is characterized in that a radiator 52 has a plurality of cooling fins 521 and guide heat pipes 522, wherein, the heat pipes 522 pass through the cooling fins 521 and an opening 521a is provided to pass through the cooling fins 521. The opening 521a is employed to be available for receiving a fan 61.

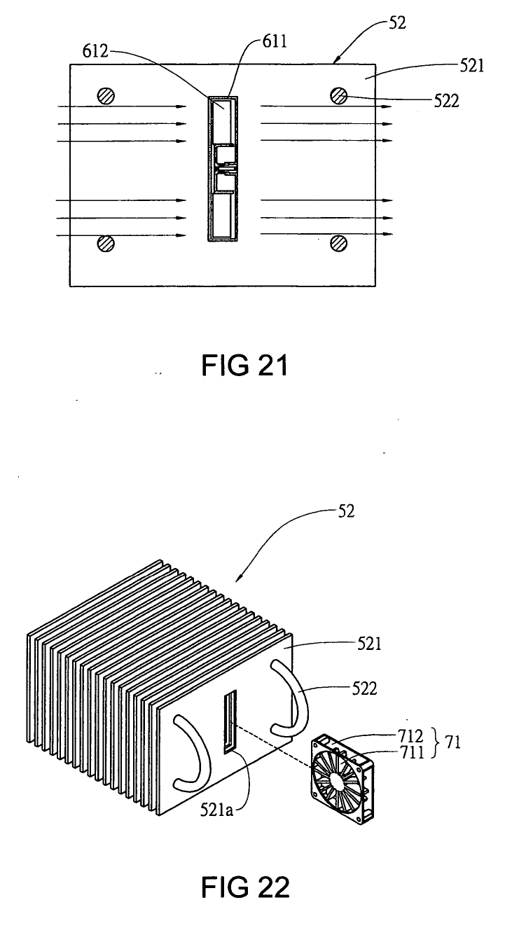

Referring to FIG. 21, the fan 61 is a vertical axial flow fan such that the air is induced into the radiator 52 from a lateral side thereof and moves outward via another lateral side thereof. When the fan blade part 611 rotates, the air enters the radiator 42 via spaces between the cooling fins 421 being interfered by the cooling fins and occurring turbulent flow as the conventional device does.

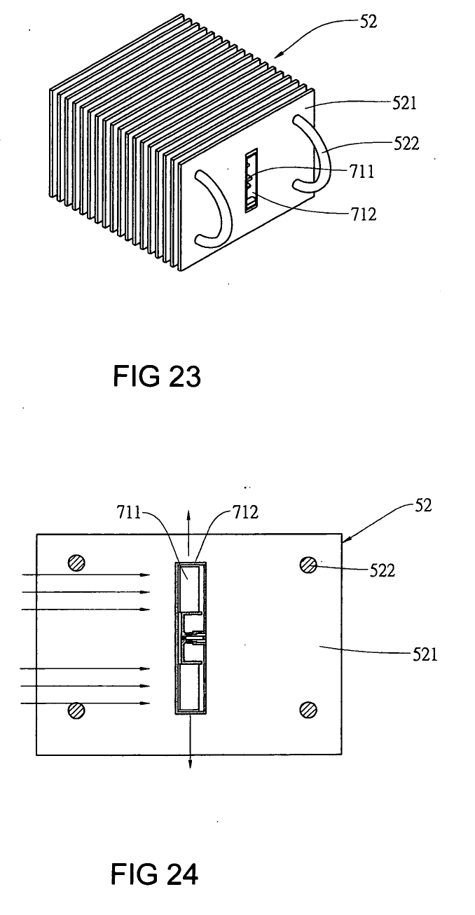

Referring to FIGS. 22 and 23, the eighth embodiment of a heat dissipating device according to the present invention is illustrated. The eighth embodiment is characterized in that a radiator 52 has a plurality of cooling fins 521 and guide heat pipes 522, wherein, the heat pipes 522 pass through the cooling fins 521 and an opening 521a is provided to pass through the cooling fins 521. The opening 521a is employed to be available for receiving a fan 71.

Referring to FIG. 24, the fan 71 is a vertical centrifugal fan such that the air is induced into the radiator 52 by the fan 71 from the top thereof and moves outward via all the lateral sides thereof. When the fan blade part 711 rotates, the air enters the radiator 52 via spaces between the cooling fins 521 being interfered by the cooling fins and occurring turbulent flow as the conventional device does.

As the foregoing, it is appreciated that comparing to the prior art, the heat dissipating device according to the present invention has the following advantages:

1. The heat dissipating device of the present invention is capable of reducing turbulent flow while the air current blows toward the radiator.

2. The heat dissipating device of the present invention is suitable for being joined to either the axial flow fan or the centrifugal fan.

While the invention has been described with referencing to preferred embodiments thereof, it is to be understood that modifications or variations may be easily made without departing from the spirit of this invention, which is defined by the appended claims.

What is claimed is:

1. A heat dissipating device, comprising:
a radiator, providing a plurality of cooling fins and an opening being disposed at a lateral side thereof to pass through the cooling fins; and
a fan, being inserted into the opening.

2. The heat dissipating device as defined in claim 1, wherein the fan is an axial flow fan.

3. The heat dissipating device as defined in claim 2, wherein the axial flow fan is a vertically disposed or horizontally disposed axial flow fan.

4. The heat dissipating device as defined in claim 1, wherein the fan is a centrifugal fan.

5. The heat dissipating device as defined in claim 4, wherein the centrifugal fan is a vertically disposed or horizontally disposed centrifugal fan.

6. A heat dissipating device, comprising:
a radiator, providing a plurality of cooling fins and guide heat pipes, the guide heat pipes passing through the cooling fins and an opening being disposed at a lateral side thereof to pass through the cooling fins; and
a fan, being inserted into the opening.

7. The heat dissipating device as defined in claim 6, wherein the fan is a vertically disposed or horizontally disposed axial flow fan.

8. The heat dissipating device as defined in claim 6, wherein the fan is a vertically disposed or horizontally disposed centrifugal fan. The heat dissipating module as defined in claim 7, wherein the rotational member has an uneven surface at a side thereof facing the stationary member.
